(19) United States
(12) Patent Application Publication
(10) Pub. No.: US 2025/0071900 A1
(43) Pub. Date: Feb. 27, 2025

(54) CIRCUIT BODY AND CONNECTOR-ATTACHED CIRCUIT BODY

(71) Applicant: Yazaki Corporation, Tokyo (JP)

(72) Inventors: Hidehiko Shimizu, Makinohara-shi (JP); Tatsuya Oga, Makinohara-shi (JP)

(21) Appl. No.: 18/801,015

(22) Filed: Aug. 12, 2024

(30) Foreign Application Priority Data
Aug. 23, 2023 (JP) 2023-135611

(51) Int. Cl. H05K 1/11; H01R 12/77; H05K 1/02

(52) U.S. Cl. CPC H05K 1/118; H01R 12/771; H05K 1/0298; H05K 2201/09781

(57) ABSTRACT

A circuit body is a flexible substrate including a plurality of conductor layers having a plurality of conductor patterns and a plurality of insulating layers arranged in a manner of sandwiching the conductor layers therebetween. In each of the conductor patterns, a contact portion is provided in a first conductor layer, and is exposed to an outside through an opening provided in a first insulating layer. A plurality of the contact portions include a first contact portion belonging to the conductor pattern extending across the first conductor layer and a second conductor layer different from the first conductor layer, and a second contact portion belonging to the conductor pattern only provided on the first conductor layer and located at a position farther from a terminal end of the flexible substrate than the first contact portion. In the second conductor layer, a dummy pattern is arranged near the first contact portion.

### CROSS-REFERENCE TO RELATED APPLICATIONS

This application is based on and claims priority under 35 USC 119 from Japanese Patent Application No. 2023-135611 filed on Aug. 23, 2023, the contents of which are incorporated herein by reference.

### TECHNICAL FIELD

The present invention relates to a circuit body including a multilayer flexible substrate and a connector-attached circuit body.

### BACKGROUND ART

The related art discloses that a flexible substrate (a flexible printed circuit (FPC)) provided with a conductor pattern is used as wiring or the like for connecting various electronic devices (for example, see Patent Literatures 1 and 2). A flexible substrate generally has a structure in which a thin-film conductor layer having a conductor pattern (that is, a circuit) of a predetermined shape is interposed between insulating films (insulating layers) and the conductor layer and the insulating layers are bonded with an adhesive. The flexible substrate is particularly characterized in that the flexible substrate can be flexibly deformed, such as curved, while maintaining electrical characteristics.

### CITATION LIST

### Patent Literature

Patent Literature 1: JP2022-089301A

Patent Literature 2: JP2002-093995A

### SUMMARY OF INVENTION

In order to mount a connector or the like (for example, a so-called SMT connector) on a flexible substrate, for example, an opening portion may be provided in an insulating layer of the flexible substrate, and a contact portion (a so-called pad portion) of a conductor pattern exposed from the opening portion and an external terminal of the connector or the like may be connected by reflow soldering or the like. In this case, in order to appropriately connect a plurality of contact portions and a plurality of external terminals with solder, it is desirable that intervals between a mounting face of the flexible substrate and the contact portions are as uniform as possible (that is, positions of the contact portions in a thickness direction are uniform).

However, in a general manufacturing method of a flexible substrate in which an insulating layer (a so-called cover film) constituting a mounting face is thermocompression-bonded with an adhesive, a thickness of the flexible substrate tends to be different between a portion where a conductor pattern is provided and a portion where no conductor pattern is provided. Specifically, a thickness of a portion where no conductor pattern is provided tends to be thinned by an amount corresponding to thinning of an adhesive layer. For example, as in a case where a contact portion located in a first conductor layer belongs to a conductor pattern extending from the first conductor layer to a second conductor layer, when there is no conductor pattern on a back face side of the contact portion (a position corresponding to a contact portion in the second conductor layer), the thickness of the flexible substrate tends to be thin in the periphery of the contact portion. As a result, the contact portion is misaligned with the other contact portions in a thickness direction, and thus intervals between the mounting face of the flexible substrate and the contact portions may be not uniform.

The present invention has been made in view of the above circumstances, and an object of the present invention is to provide a circuit body capable of making positions in a thickness direction of a plurality of contact portions of a plurality of conductor patterns uniform in the thickness direction of a flexible substrate.

In order to achieve the above object, a circuit body and a connector-attached circuit body according to the present invention have the following features.

A circuit body of the present invention includes a multilayer flexible substrate. The multilayer flexible substrate includes a plurality of conductor layers having a plurality of conductor patterns for implementing a circuit configuration, and a plurality of insulating layers arranged in a manner of sandwiching the plurality of conductor layers therebetween. In each of the plurality of the conductor patterns, a contact portion is provided in a first conductor layer adjacent to a first insulating layer among the plurality of conductor layers, and is exposed to an outside through an opening provided in the first insulating layer constituting a mounting face of the flexible substrate among the plurality of insulating layers to be connected to an external terminal. A plurality of the contact portions include a first contact portion belonging to the conductor pattern, the conductor pattern extending across the first conductor layer and a second conductor layer different from the first conductor layer, and a second contact portion that is different from the first contact portion and that is located at a position farther from a terminal end of the flexible substrate than the first contact portion. In the second conductor layer, a dummy pattern, which is the conductor pattern that does not contribute to the circuit configuration, is arranged on at least one of a corresponding position corresponding to the first contact portion and a vicinity of the corresponding position in a thickness direction of the flexible substrate.

A connector-attached circuit of the present invention includes the above circuit body and a connector that is to be mounted on the mounting face of the circuit body and has a plurality of the external terminals to be connected to the plurality of the contact portions.

According to the circuit body and the connector-attached circuit body of the present invention, the first contact portion belongs to the conductor pattern provided in a manner of extending across the first conductor layer and the second conductor layer among the plurality of conductor patterns provided in the multilayer flexible substrate. Further, the dummy pattern is arranged in the second conductor layer on at least one of a corresponding position corresponding to the first contact portion and the vicinity of the corresponding position. Accordingly, the flexible substrate at a position corresponding to the first contact portion is less likely to be thinned in the thickness direction as compared with a case where there is no dummy pattern in the second conductor layer. Therefore, positions of the first contact portion and the second contact portion can be made uniform even when the positions of the first contact portion and the second contact portion are likely to be misaligned in the thickness direction as in a case where the first contact portion is closer to the terminal end portion of the flexible substrate than the other second contact portion. Therefore, in the circuit body and the connector-attached circuit body having the present configuration, positions of a plurality of contact portions of a plurality of conductor patterns can be made uniform in the thickness direction of the flexible substrate.

The present invention has been briefly described above. Details of the present invention can be clarified by reading modes (hereinafter, referred to as “embodiments”) for carrying out the invention to be described below with reference to the accompanying drawings.

### BRIEF DESCRIPTION OF DRAWINGS

FIG. 1 is a perspective view showing a circuit body according to an embodiment of the present invention;

FIG. 2 is a top view showing the circuit body shown in FIG. 1;

FIG. 3 is a cross-sectional view taken along a line A-A in FIG. 2;

FIG. 4 is a cross-sectional view taken along a line B-B in FIG. 2;

FIG. 5 is a cross-sectional view taken along a line C-C in FIG. 2;

FIG. 6 is a view showing a circuit body according to a modification corresponding to FIG. 2; and

FIG. 7 is a view showing a circuit body according to another modification corresponding to FIG. 2.

### DESCRIPTION OF EMBODIMENTS

### Embodiment

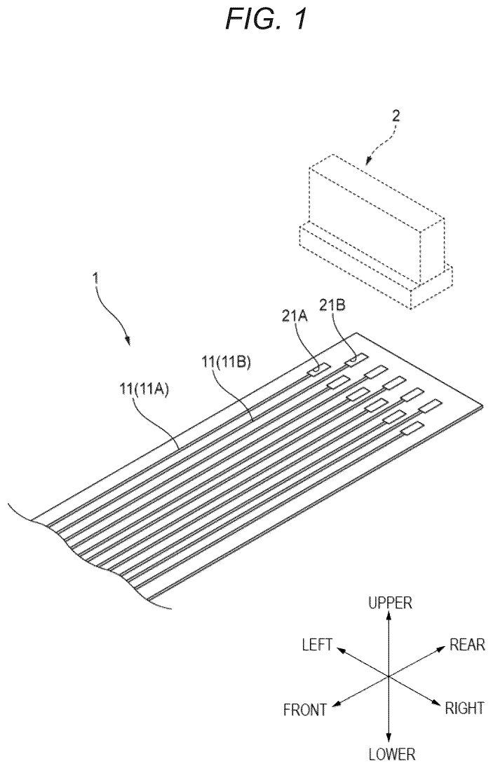

Hereinafter, a circuit body 1 according to an embodiment of the present invention (the present embodiment) will be described with reference to the drawings. For convenience of description, a “front-rear direction”, a “left-right direction”, and an “upper-lower direction” are defined as shown in FIG. 1 and the like. The “front-rear direction”, the “left-right direction”, and the “upper-lower direction” are orthogonal to one another. The front-rear direction, the left-right direction, and the upper-lower direction respectively correspond to a longitudinal direction, a lateral direction, and a thickness direction of the circuit body 1.

As shown in FIGS. 1 to 5, the circuit body 1 according to the present embodiment is implemented by a multilayer substrate (a flexible printed circuit (FPC)) including a pair of upper and lower conductor layers 10A and 10B having conductor patterns 11 formed of a thin-film conductor for implementing a circuit configuration, and a plurality of insulating layers 20A, 20B, and 20C arranged in a manner of sandwiching the conductor layers 10A and 10B therebetween.

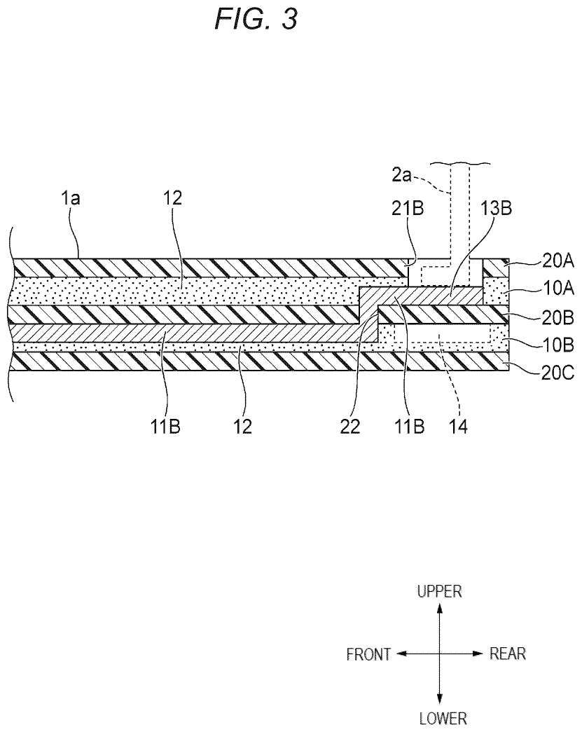

Specifically, as shown in FIGS. 3 to 5, the upper conductor layer 10A is interposed between the insulating layer 20A constituting a mounting face (an upper face) la of the flexible substrate and the insulating layer 20B positioned below the insulating layer 20A, and the lower conductor layer 10B is interposed between the insulating layer 20B and the insulating layer 20C that is positioned below the insulating layer 20B and constitutes a lower face of the flexible substrate. An adhesive 12 that has a function of bonding the insulating layers 20A and 20B to each other is present in a space of the conductor layer 10A other than a space occupied by the conductor pattern 11. Similarly, the adhesive 12 that has a function of bonding the insulating layers 20B and 20C to each other is present in a space of the conductor layer 10B other than a space occupied by the conductor pattern 11.

The circuit body 1 includes, as the conductor patterns 11, a plurality of conductor patterns 11A provided only in the conductor layer 10A, and a plurality of conductor patterns 11B provided in a manner of extending over the conductor layer 10A and the conductor layer 10B.

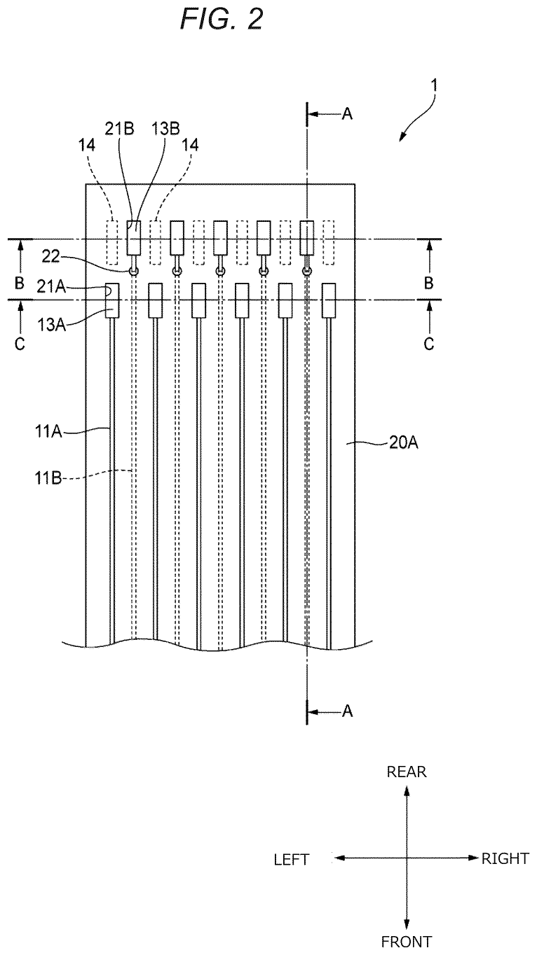

The plurality of conductor patterns 11A are arranged at intervals in the left-right direction, and extend in the front-rear direction in the conductor layer 10A only (see FIG. 2). Terminal end portions in the rear of the plurality of conductor patterns 11A are positioned in front of a terminal end portion of the circuit body 1 by a predetermined distance, and are arranged at intervals in the left-right direction. An opening portion 21A is formed in the insulating layer 20A located on an upper side of the terminal end portion in the rear of each conductor pattern 11A, and the terminal end portion in the rear of each conductor pattern 11A is exposed to the outside through the corresponding opening portion 21A (see FIG. 2). The terminal end portion in the rear of each conductor pattern 11A functions as a contact portion (a so-called pad portion) 13A.

The plurality of conductor patterns 11B are positioned between the plurality of conductor patterns 11A in the left-right direction, and extend in the front-rear direction across the conductor layer 10A and the conductor layer 10B (see FIG. 2). Specifically, as shown in FIGS. 2 and 3, in a region in front of a through hole 22 that is located in the rear of the contact portion 13A of the conductor pattern 11A, is formed in the insulating layer 20B, and extends in the upper-lower direction, each conductor pattern 11B extends in the front-rear direction in the conductor layer 10B, at a position of the through hole 22 extending in the front-rear direction, each conductor pattern 11B extends in the upper-lower direction so as to pass through the through hole 22 and connect the conductor layer 10B and the conductor layer 10A, and in a region in the rear of the through hole 22, each conductor pattern 11B extends in the front-rear direction in the conductor layer 10A. Terminal end portions in the rear of the plurality of conductor patterns 11B (located in the conductor layer 10A) are positioned in the vicinity of a rear end of the circuit body 1 at positions in the rear of the contact portions 13A of the conductor patterns 11A (at positions closer to the rear end of the circuit body 1 than the contact portions 13A), and are arranged at intervals in the left-right direction. An opening portion 21B is formed in the insulating layer 20A located on an upper side of the terminal end portion in the rear of each conductor pattern 11B, and the terminal end portion in the rear of each conductor pattern 11B is exposed to the outside through the corresponding opening portion 21B (see FIG. 2). The terminal end portion in the rear of each conductor pattern 11B functions as a contact portion (a so-called pad portion) 13B.

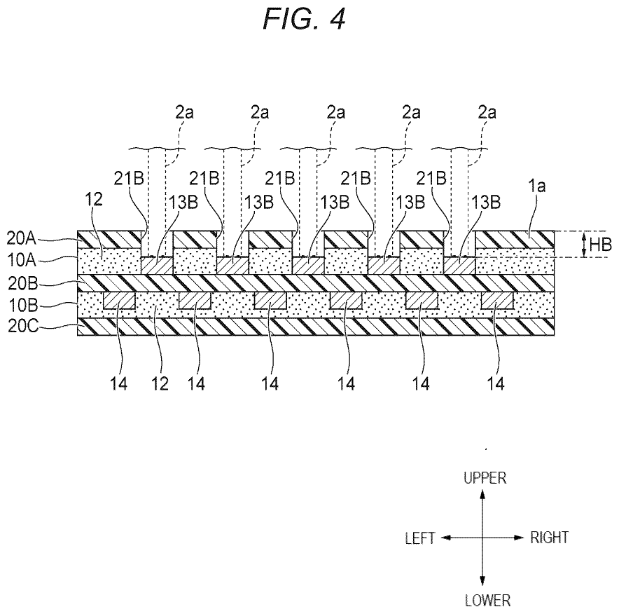

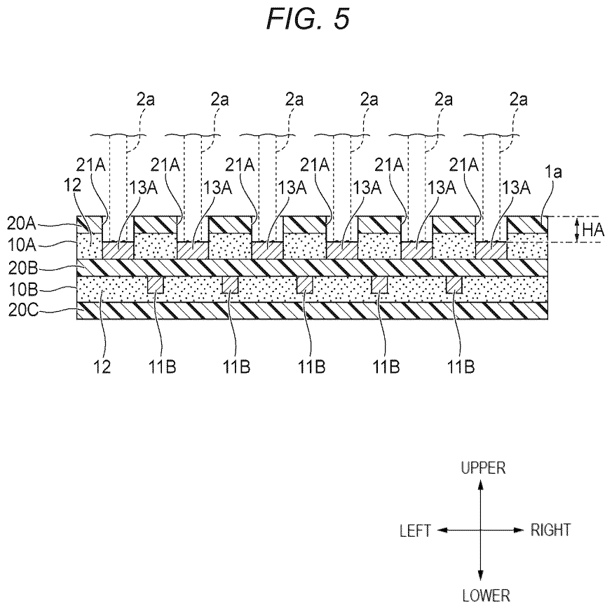

In the conductor layer 10B located below the plurality of contact portions 13B arranged in the left-right direction, a plurality of dummy patterns 14 formed of thin-film conductors that do not contribute to a circuit configuration are arranged in the left-right direction at positions where the plurality of conductor patterns 11A are arranged (see FIG. 2). In other words, the plurality of dummy patterns 14 are arranged at positions adjacent to the plurality of contact portions 13B in a plate face direction (the left-right direction) of the circuit body 1 (the flexible substrate). Accordingly, as compared with a case where no dummy pattern 14 is provided in the conductor layer 10B, the conductor layer 10B located below the plurality of contact portions 13B is less likely to be thinned when the flexible substrate is manufactured. As a result, when a position in a thickness direction of a mounting face la around a peripheral edge of the opening portion 21A where the second contact portion 13A is exposed is defined as a reference face position, there is no difference between an interval HB (see FIG. 4) in the upper-lower direction between the contact portion 13B and the reference face position and an interval HA (see FIG. 5) in the upper-lower direction between the contact portion 13A and the reference face position. In other words, positions of the plurality of contact portions 13A and the plurality of contact portions 13B in the upper-lower direction (a thickness direction of the circuit body 1) are made uniform.

To the plurality of contact portions 13A and 13B exposed from the plurality of opening portions 21A and 21B of the circuit body 1 configured as described above, for example, a plurality of terminals 2a arranged corresponding to the plurality of contact portions 13A and 13B of a surface mount (SMT) connector 2 (see FIG. 1) are connected by soldering or the like using a reflow method (see FIGS. 3 to 5). Here, as described above, since the positions of the plurality of contact portions 13A and the plurality of contact portions 13B in the upper-lower direction (the thickness direction of the circuit body 1) are made uniform by arranging the plurality of dummy patterns 14 in the conductor layer 10B in the present embodiment, the plurality of contact portions 13A and 13B and the plurality of terminals 2a of the connector 2 are easily connected by soldering more appropriately.

### Operations and Effects

As described above, according to the circuit body 1 in the present embodiment, the contact portion 13B belongs to the conductor pattern 11B that extends across the conductor layer 10A and the conductor layer 10B among the plurality of conductor patterns 11A and 11B provided in the multilayer flexible substrate. Further, the dummy pattern 14 is arranged in the vicinity of the contact portion 13B in the conductor layer 10B. Accordingly, as compared with a case where no dummy pattern 14 is provided in the conductor layer 10B, the thickness of the flexible substrate at a position corresponding to the contact portion 13B is less likely to be reduced when the flexible substrate is manufactured. Accordingly, positions of the contact portion 13A and the contact portion 13B can be made uniform even when the positions of the contact portion 13A and the contact portion 13B are likely to be misaligned in the thickness direction as in the present embodiment in which the contact portion 13B is closer to the terminal end portion of the flexible substrate than the contact portion 13A belonging to the conductor pattern 11A provided in the conductor layer 10A only. Accordingly, in the circuit body 1 according to the present embodiment, the positions of the plurality of contact portions 13A and 13B of the plurality of conductor patterns 11A and 11B can be made uniform in the thickness direction of the flexible substrate.

### Other Embodiments

The present invention is not limited to the embodiment described above, and various modifications can be adopted within the scope of the present invention. For example, the present invention is not limited to the embodiment described above, and modifications, improvements, and the like can be appropriately made. In addition, materials, shapes, sizes, numbers, arrangement positions, or the like of components in the embodiment described above are freely selected and are not limited as long as the present invention can be implemented.

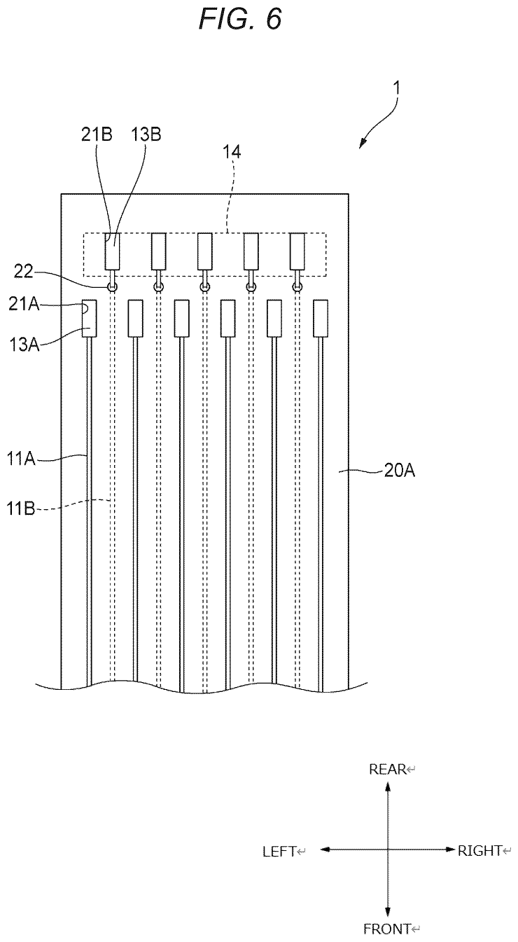

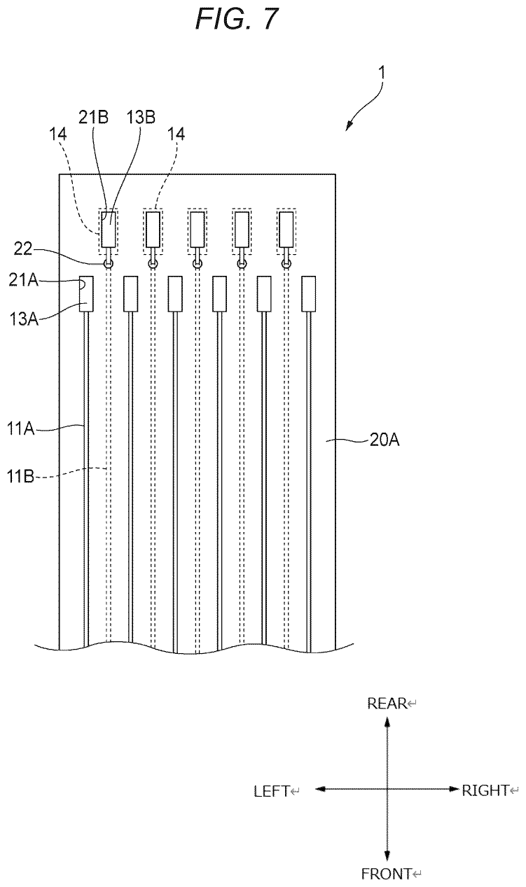

For example, in the above embodiment, in the conductor layer 10B located below the plurality of contact portions 13B, the plurality of dummy patterns 14 are arranged in the left-right direction at positions (positions adjacent to the plurality of contact portions 13B in the left-right direction) where the plurality of conductor patterns 11A are arranged (see FIG. 2). On the other hand, as shown in FIG. 6, in the conductor layer 10B located below the plurality of contact portions 13B, one dummy pattern 14 elongated in the left-right direction may be arranged in a manner of extending over a range in the left-right direction including all of the plurality of contact portions 13B. Furthermore, as shown in FIG. 7, in the conductor layer 10B located below the plurality of contact portions 13B, a plurality of dummy patterns 14 may be arranged in a manner of overlapping lower sides of the plurality of contact portions 13B (at the same positions as the plurality of contact portions 13B in the left-right direction).

Here, features of the embodiment of the circuit body 1 and the connector-attached circuit body (1+2) according to the present invention described above are briefly summarized and listed in the following [1] to [3].
[1] A circuit body (1) implemented by a multilayer flexible substrate includes a plurality of conductor layers (10A and 10B) having conductor patterns (11) for implementing a circuit configuration, and a plurality of insulating layers (20A, 20B, and 20C) arranged in a manner of sandwiching the plurality of conductor layers (10A and 10B) therebetween. In a first conductor layer (10A) adjacent to a first insulating layer (20A) among the plurality of conductor layers, each of a plurality of the conductor patterns (11) has a contact portion (13A, 13B) that is exposed to the outside through an opening portion (21A, 21B) provided in the first insulating layer (20A) constituting a mounting face (1a) of the flexible substrate among the plurality of insulating layers and is to be connected to an external terminal (2a).

A plurality of the contact portions include
a first contact portion (13B) belonging to the conductor pattern (11B) that extends across the first conductor layer (10A) and a second conductor layer (10B) different from the first conductor layer (10A), and
a second contact portion (13A) that is different from the first contact portion (13B) and is located at a position farther from a terminal end portion of the flexible substrate than the first contact portion (13B).

A dummy pattern (14), which is the conductor pattern that does not contribute to the circuit configuration, is arranged in the second conductor layer (10B) on at least one of a corresponding position corresponding to the first contact portion (13B) and a vicinity of the corresponding position in a thickness direction of the flexible substrate.

According to the circuit body having the above configuration [1], the first contact portion belongs to the conductor pattern that extends across the first conductor layer and the second conductor layer among the plurality of conductor patterns provided in the multilayer flexible substrate. Further, the dummy pattern is arranged in the second conductor layer on at least one of a corresponding position corresponding to the first contact portion and the vicinity of the corresponding position. Accordingly, the flexible substrate at a position corresponding to the first contact portion is less likely to be thinned in the thickness direction as compared with a case where there is no dummy pattern in the second conductor layer. Therefore, positions of the first contact portion and the second contact portion can be made uniform even when the positions of the first contact portion and the second contact portion are likely to be misaligned in the thickness direction as in a case where the first contact portion is closer to the terminal end portion of the flexible substrate than the other second contact portion. Therefore, in the circuit body having the present configuration, positions of a plurality of contact portions of a plurality of conductor patterns can be made uniform in the thickness direction of the flexible substrate.
[2] In the circuit body (1) according to the above [1],
in a case that the mounting face (1a) around a peripheral edge of the opening portion (21A) where the second contact portion (13A) is exposed is defined as a reference face position,
   the dummy pattern (14) is arranged such that a difference between an interval (HB) in the thickness direction between the first contact portion (13B) and the reference face position and an interval (HA) in the thickness direction between the second contact portion (13A) and the reference face position is close to zero.

According to the circuit body having the above configuration [2], the dummy pattern is arranged such that there is no difference between the interval between the second contact portion and the mounting face at a position where the second contact portion is provided and the interval between the first contact portion and the mounting face at a position where the first contact portion is provided. Therefore, in the circuit body having the present configuration, positions of a plurality of contact portions of a plurality of conductor patterns can be made uniform in the thickness direction of the flexible substrate.
[3] In the circuit body (1) according to the above [1],
the dummy pattern (14) is arranged in a manner of sandwiching the corresponding position in a plate face direction of the flexible substrate.

According to the circuit body having the above configuration [3], the positions of the plurality of contact portions of the plurality of conductor patterns can be made uniform in the thickness direction of the flexible substrate by arranging the dummy pattern at a position adjacent to the first contact portion in the plate face direction of the flexible substrate.
[4] A connector-attached circuit body (1+2) including:
the circuit body (1) according to any one of [1] to [3]; and
a connector (2) that is to be mounted on the mounting face (1a) of the circuit body (1) and has a plurality of the external terminals (2a) to be connected to the plurality of the contact portions (13A and 13B).

According to the connector-attached circuit body having the above configuration [4], the first contact portion belongs to the conductor pattern that extends across the first conductor layer and the second conductor layer among the plurality of conductor patterns provided in the multilayer flexible substrate. Further, the dummy pattern is arranged in the second conductor layer on at least one of a corresponding position corresponding to the first contact portion and the vicinity of the corresponding position. Accordingly, the flexible substrate at a position corresponding to the first contact portion is less likely to be thinned in the thickness direction as compared with a case where there is no dummy pattern in the second conductor layer. Therefore, positions of the first contact portion and the second contact portion can be made uniform even when the positions of the first contact portion and the second contact portion are likely to be misaligned in the thickness direction as in a case where the first contact portion is closer to the terminal end portion of the flexible substrate than the other second contact portion. Therefore, in the connector-attached circuit body having the present configuration, positions of the plurality of contact portions of the plurality of conductor patterns can be made uniform in the thickness direction of the flexible substrate.

What is claimed is:

1. A circuit body implemented by a multilayer flexible substrate,
the multilayer flexible substrate including
a plurality of conductor layers having a plurality of conductor patterns for implementing a circuit configuration, and
a plurality of insulating layers arranged in a manner of sandwiching the plurality of conductor layers therebetween, wherein
in each of the plurality of the conductor patterns, a contact portion is provided in a first conductor layer adjacent to a first insulating layer among the plurality of conductor layers, and is exposed to an outside through an opening provided in the first insulating layer constituting a mounting face of the flexible substrate among the plurality of insulating layers to be connected to an external terminal,
a plurality of the contact portions include
a first contact portion belonging to the conductor pattern, the conductor pattern extending across the first conductor layer and a second conductor layer different from the first conductor layer, and
a second contact portion that is different from the first contact portion and that is located at a position farther from a terminal end of the flexible substrate than the first contact portion, and
in the second conductor layer, a dummy pattern, which is the conductor pattern that does not contribute to the circuit configuration, is arranged on at least one of a corresponding position corresponding to the first contact portion and a vicinity of the corresponding position in a thickness direction of the flexible substrate.

2. The circuit body according to claim 1, wherein
in a case that the mounting face around a peripheral edge of the opening portion where the second contact portion is exposed is defined as a reference face position,
the dummy pattern is arranged such that a difference between an interval in the thickness direction between the first contact portion and the reference face position and an interval in the thickness direction between the second contact portion and the reference face position is close to zero.

3. The circuit body according to claim 1, wherein
the dummy pattern is arranged so as to sandwich the corresponding position in a plate face direction of the flexible substrate.

4. A connector-attached circuit body comprising:
the circuit body according to claim 1; and
a connector that is to be mounted on the mounting face of the circuit body and has a plurality of the external terminals to be connected to the plurality of the contact portions.
